(19) United States
(12) Patent Application Publication
(10) Pub. No.: US 2009/0218582 A1
(43) Pub. Date: Sep. 3, 2009

(54) OPTICAL DEVICE AND METHOD OF FABRICATING THE SAME

(76) Inventors: Wei-Hung KANG, Hsinchu (TW); Chia-Yang Chang, Hsinchu (TW); Jung-Jung Kuo, Hsinchu (TW)

Correspondence Address: Muncy, Geissler, Olds & Lowe, PLLC, P.O. BOX 1364, FAIRFAX, VA, 22038-1364, US

(21) Appl. No.: 12/039,399

(22) Filed: Feb. 28, 2008

(51) Int. Cl. H01L 33/00; H01L 21/48

(52) U.S. Cl. 257/98; 438/29; 257/E33.073

(57) ABSTRACT

A method of fabricating an optical device is disclosed. The method comprises the step of forming an optical stack of laminated lenses and a phosphor film therebetween. The method further comprises the step of attaching the optical stack to an LED die. In addition, an optical device fabricated by the above method is also disclosed.

### BACKGROUND OF THE INVENTION

1. Field of the Invention

The present invention relates to an optical device, and in particular relates to an optical device in which the LED die is not directly connected to the phosphor material.

2. Description of the Related Art

In conventional skills, several methods for packing an optical device such as a high power chip are as following.

Referring to FIG. 1a, a conventional optical device includes a reflector cup 10, an LED die 12 on the reflector cup 10, a phosphor powered layer 14 of different thicknesses covering at least the LED die 12, epoxy 10 for attaching the LED die 12 to the reflector cup 10, and glue 16 for packing the optical device.

Referring to FIG. 1b, a conventional optical device includes a reflector cup 100, a submount die 102 on the reflector cup 100, an LED die 104 on the submount die 102, a phosphor powered layer 106 of an uniform thickness covering at least the LED die 104, epoxy 110 for attaching the LED die 104 to the reflector cup 100, and glue 108 for packing the optical device.

However, no matter how the profile of the phosphor powered layer is formed, light output efficiency degrades because the phosphor powered layer directly contacts the LED die. This severely affects performance of the optical device.

Accordingly, an optical device capable of enhancing light output efficiency and fabrication methods thereof is desirable.

### BRIEF SUMMARY OF THE INVENTION

In one embodiment, a method of fabricating an optical device is disclosed. The method comprises the step of forming an optical stack of laminated lenses and a phosphor film therebetween. The method further comprises the step of attaching the optical stack to an LED die.

In another embodiment, an optical device is also disclosed. The optical device comprises an LED die on a base, an adhesive material covering the LED die, an optical stack of laminated lenses and a phosphor film therebetween. The optical stack is over the LED die and is attached thereto by means of the adhesive material.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIGS. 1A and 1B are cross sections of a conventional optical device; and

FIG. 2A˜2G are cross sections of one embodiment for a method of fabricating an optical device.

FIG. 3 is a schematic view showing the demolding process.

FIG. 4 is a schematic view showing an optical stack array including a plurality of isolated optical stacks.

FIG. 5 is a schematic view showing an optical device subject to a reliability test.

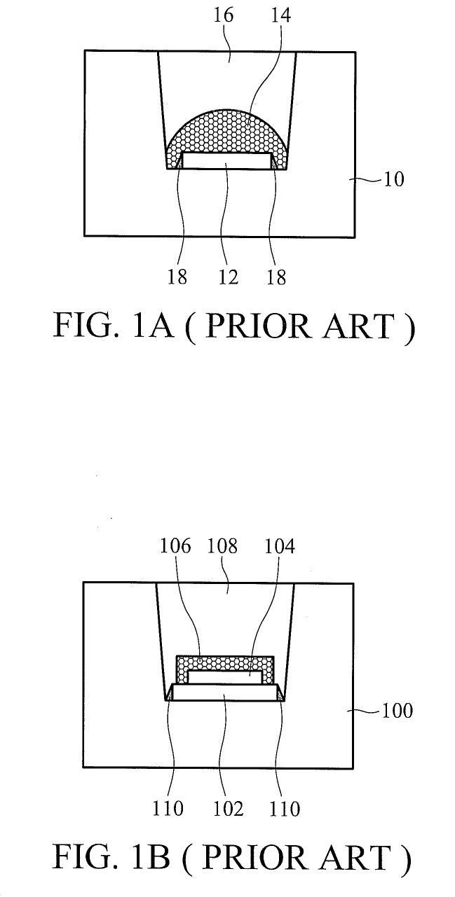

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

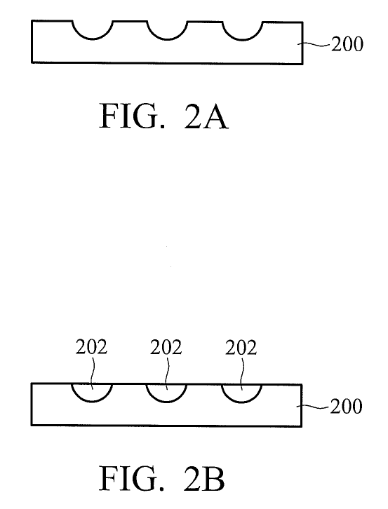

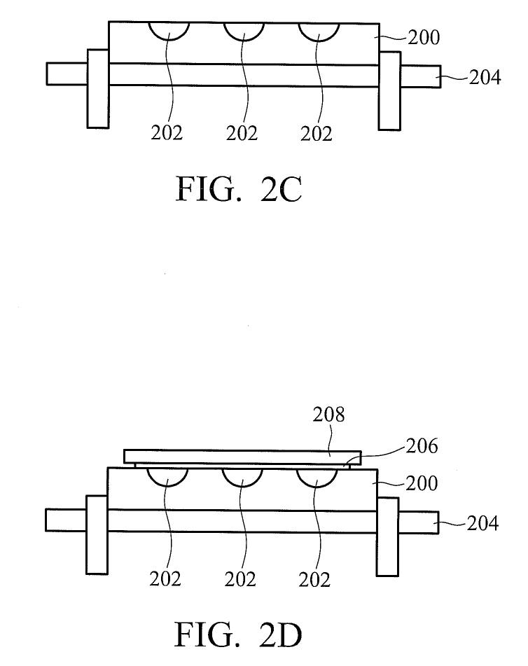

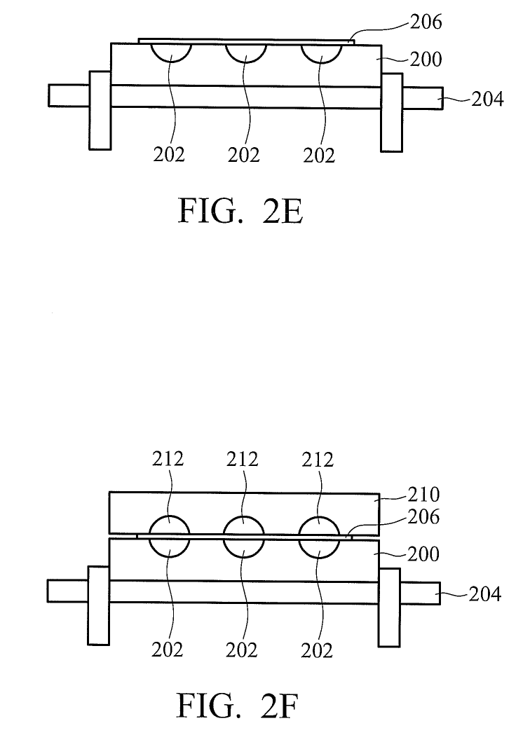

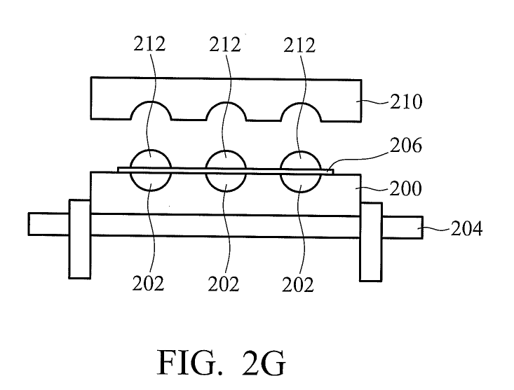

FIG. 2A˜2G are cross sections of one embodiment for a method of fabricating an optical device.

As shown in FIG. 2A, a mold 200 is provided. The mold 200, for example, is made up of a metal material, a plastic material or a ceramic material. At the same time, another mold, such as the mold 210 shown in FIG. 2F, can be prepared in the step.

As shown in FIG. 2B, an optical material is dispensed to the molds 200 and 210 in sequence, thus forming lenses 202 and 212 therein, respectively. The lenses 202 or 212 consist of a lens array, and the lenses 202 and 212 use transparent polymer materials. The step of dispensing an optical material to each mold to form lenses therein employs a mesh print process. It is noted that only the mold 200 possessing lenses 202 therein is shown here for purpose of simplicity.

As shown in FIG. 2C, the mold 200 possessing lenses 202 therein is then disposed on a tooling 204. The tooling 204 may be made up of metal.

As shown in FIG. 2D, a phosphor film 206 is formed on a substrate 208, and the processing continues to let the phosphor film 206 face the lens array of the mold 200 when attaching the substrate 208 thereto. As a result, the phosphor film 206 attaches to the lens array of the mold 200. Attachment of the phosphor film 206 to the lens array of the mold 200 can be carried out using any suitable adhesive materials.

Thereafter, as shown in FIG. 2E, the substrate 208 is removed from the phosphor film 206. Removal of the substrate 208 from the phosphor film 206 can use any suitable methods. The substrate 208 is made up of transparent materials. In other embodiments, the substrate 208 is not removed.

As shown in FIG. 2F, the mold 210 with the lenses 212 facing downward which can be prepared in previous steps is attached to the phosphor film 206 in a manner that each of the lenses 212 is opposite to each of the lenses 202. Attachment of the mold 210 with the lenses 212 to the phosphor film 206 can be carried out using any suitable adhesive materials.

As shown in FIG. 2G, the processing continues to perform a demolding step so that the mold 210 is removed from the lenses 212 and the phosphor film 206.

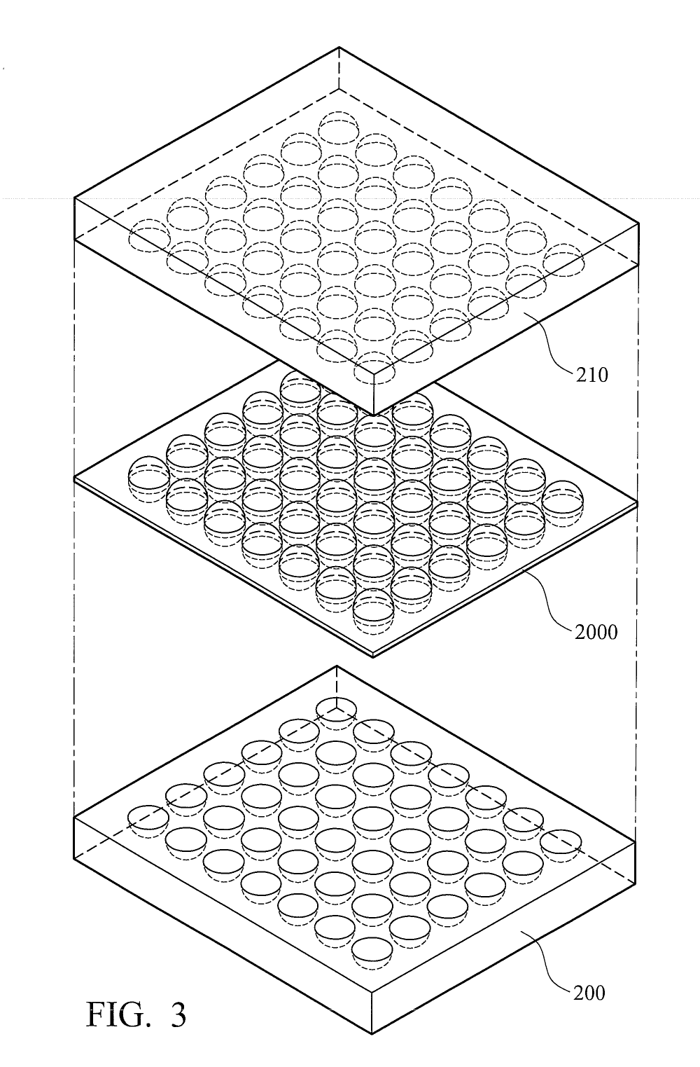

Referring to FIG. 3, it depicts demolding step in which the molds 210 and 200 are peeled off, thus, a structure 2000 including a lot of connected optical stacks consisting of an upper lens 212, a lower lens 202 and a phosphor film 206 therebetween is obtained.

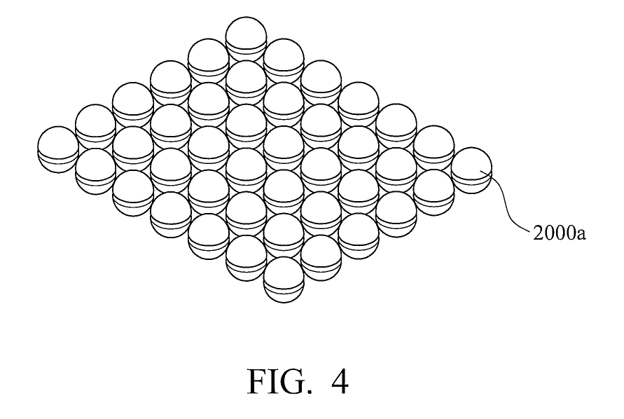

As shown in FIG. 4, various isolated optical stacks 2000a are obtained after a cutting step. Each optical stack can be utilized for packing of an optical device.

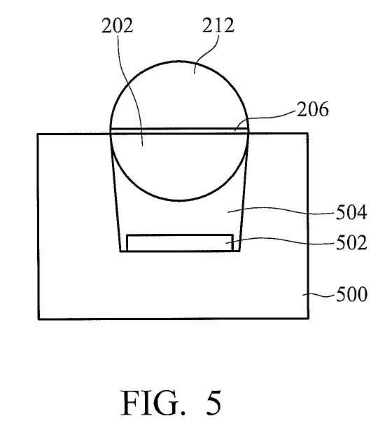

As shown in FIG. 5, an optical stack consisting of an upper lens 212, a lower lens 202 and a phosphor film 206 therebetween is attached to a base 500 with an LED die 502 thereon by means of an adhesive material 504 such as glue. In doing so, the phosphor film 206 dose not contact the LED die 502 so that emission efficiency of the LED die 502 won't degrade.

Although the surfaces of the laminated lenses 202 and 212 not connected to the phosphor film 206 are shaped in convex, they can be shaped in concave or have other desirable shapes in other embodiments.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method of fabricating an optical device, comprising:
forming an optical stack of laminated lenses and a phosphor film therebetween; and
attaching the optical stack to an LED die on a base using an adhesive material.

2. The method as claimed in claim 1, wherein formation of the optical stack comprises:
providing first and second molds, wherein each mold possesses a lens array therein;
attaching the phosphor film to the lens array of one of the first and second molds;
assembling the first and second molds with the phosphor film therebetween; and
performing a demolding step of the first and second molds.

3. The method as claimed in claim 2, wherein providing of the first and second molds possessing the lens array therein comprises:
dispensing an optical material to each mold to form lenses therein, wherein the lenses consists of the lens array.

4. The method as claimed in claim 2, wherein the step of attaching the phosphor film to the lens array of one of the first and second molds comprises:
forming the phosphor film on a substrate;
letting the phosphor film face the lens array of one of the first and second molds when attaching the substrate thereto; and
removing the substrate from the phosphor film.

5. The method as claimed in claim 2, wherein the step of dispensing an optical material to each mold to form lenses therein employs a mesh print process.

6. The method as claimed in claim 2, wherein materials of the first and second molds include a metal material, a plastic material or a ceramic material.

7. The method as claimed in claim 1, wherein surfaces of the laminated lenses not being connected to the phosphor film are shaped in convex or concave.

8. The method as claimed in claim 1, wherein the laminated lenses use transparent polymer materials.

9. An optical device, comprising:
an LED die on a base;
an adhesive material covering the LED die;
an optical stack of laminated lenses and a phosphor film therebetween, wherein the optical stack is over the LED die and is attached thereto by means of the adhesive material.

10. The optical device as claimed in claim 9, wherein surfaces of the laminated lenses not being connected to the phosphor film are shaped in convex or concave.

11. The optical device as claimed in claim 9, wherein the laminated lenses use transparent polymer materials.
